(19) United States
(12) Patent Application Publication
(10) Pub. No.: US 2019/0008038 A1
(43) Pub. Date: Jan. 3, 2019

(54) FLEXIBLE WIRING PLATE AND DISPLAY DEVICE

(71) Applicant: JOLED INC., Tokyo (JP)

(72) Inventor: Yutaka NAKANO, Tokyo (JP)

(73) Assignee: JOLED INC., Tokyo (JP)

(21) Appl. No.: 15/988,682

(22) Filed: May 24, 2018

(30) Foreign Application Priority Data
Jun. 29, 2017 (JP) 2017-127142

(51) Int. Cl. H05K 1/02; H05K 1/18

(52) U.S. Cl. CPC H05K 1/0281; H05K 1/189; H05K 3/361; H05K 2203/166; H05K 1/0266

(57) ABSTRACT

A flexible wiring plate is an elongated flexible wiring plate to be connected to a display panel. The flexible wiring plate has a shape retention structure which prevents the warp of the flexible wiring plate at ends in the longitudinal direction of the flexible wiring plate in a lateral view of the flexible wiring plate.

### CROSS REFERENCE TO RELATED APPLICATIONS

The present application is based on and claims priority of Japanese Patent Application No. 2017-127142 filed on Jun. 29, 2017. The entire disclosure of the above-identified application, including the specification, drawings and claims is incorporated herein by reference in its entirety.

### FIELD

The present disclosure relates to flexible wiring plates, and display devices including the flexible wiring plates.

### BACKGROUND

A conventional display panel using organic electroluminescence (EL) is connected through a flexible substrate (a flexible wiring plate) to a print substrate which feeds power supply or signals to the drive circuit of the display panel. For example, Patent Literature 1 discloses formation of an alignment mark having a predetermined shape (such as an elliptical shape) in a flexible wiring plate to prevent positional deviation in the rotational direction when the flexible wiring plate is connected to a display panel.

### CITATION LIST

### Patent Literature

Patent Literature 1: Japanese Unexamined Patent Application Publication No. 2002-329941

### SUMMARY

### Technical Problem

In an operation to connect a flexible wiring plate to a display panel, the flexible wiring plate is lifted up with two arms, and is transferred to the display panel disposed in place. The flexible wiring plate is then positioned to the display panel.

Unfortunately, in the case where the flexible wiring plate has an excessively large size (for example, the length in the longitudinal direction is excessively long), the ends of the flexible wiring plate in the longitudinal direction may curve downward when the flexible wiring plate is lifted up with the arms, leading to difficulties in positioning of the flexible wiring plate to the display panel.

The present disclosure has been made in consideration of the problem. An object of the present disclosure is to provide a flexible wiring plate which can be readily positioned to a display panel even when the flexible wiring plate has a large size, and a display device including the flexible wiring plate.

### Solution to Problem

To achieve the object, a flexible wiring plate according to one aspect of the present disclosure is an elongated flexible wiring plate to be connected to a display panel. The flexible wiring plate has a shape retention structure which prevents warp of the flexible wiring plate at ends in the longitudinal direction of the flexible wiring plate in a lateral view of the flexible wiring plate.

To achieve the object, the display device according to one aspect of the present disclosure includes a display panel, and the flexible wiring plate described above.

### Advantageous Effects

The present disclosure can provide a flexible wiring plate which can be readily positioned to a display panel even when the flexible wiring plate has a large size, and a display device including the flexible wiring plate.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1 is a perspective view illustrating one example of a display device including a display module according to Embodiment 1.

FIG. 2 is a schematic view illustrating a configuration of the display module according to Embodiment 1.

FIG. 3 is a sectional view illustrating a wiring plate according to Embodiment 1, which is taken along the III-III line in FIG. 2.

FIG. 4 is a diagram illustrating a state where the wiring plate according to Embodiment 1 is lifted up.

FIG. 5A is a schematic view illustrating a configuration of a wiring plate according to Comparative Example 1.

FIG. 5B is a diagram illustrating a state where the wiring plate according to Comparative Example 1 is lifted up.

FIG. 6A is a schematic view illustrating the press bonding positions of a wiring plate according to Comparative Example 2, which vary according to the size of the wiring plate.

FIG. 6B is a schematic view illustrating the press bonding positions of the wiring plate according to Embodiment 1, which vary according to the size of the wiring plate.

FIG. 7A is a schematic view illustrating a configuration of a wiring plate according to Embodiment 2.

FIG. 7B is a diagram illustrating a state where the wiring plate according to Embodiment 2 is lifted up.

### DESCRIPTION OF EMBODIMENTS

Embodiments of the present disclosure will now be described with reference to the drawings. The embodiments described below all illustrate specific examples of the present disclosure.

Accordingly, numeral values, shapes, materials, components, arrangements, positions, and connection forms of the components, steps, order of the steps, and the like shown in the embodiments below are only examples, and will not limit the present disclosure.

Among the components of the embodiments below, the components not described in an independent claim representing the most superordinate concept of the present disclosure are described as arbitrary components.

The drawings are schematic views, and are not always strictly illustrated. In the drawings, identical reference numerals are given to substantially the same configurations, and the duplication of description thereof will be omitted or simplified.

In this specification, the terms “substantially” and “about” mean that production errors and dimensional tolerance are included.

### Embodiment 1

### [1-1. Configuration of Display Module]

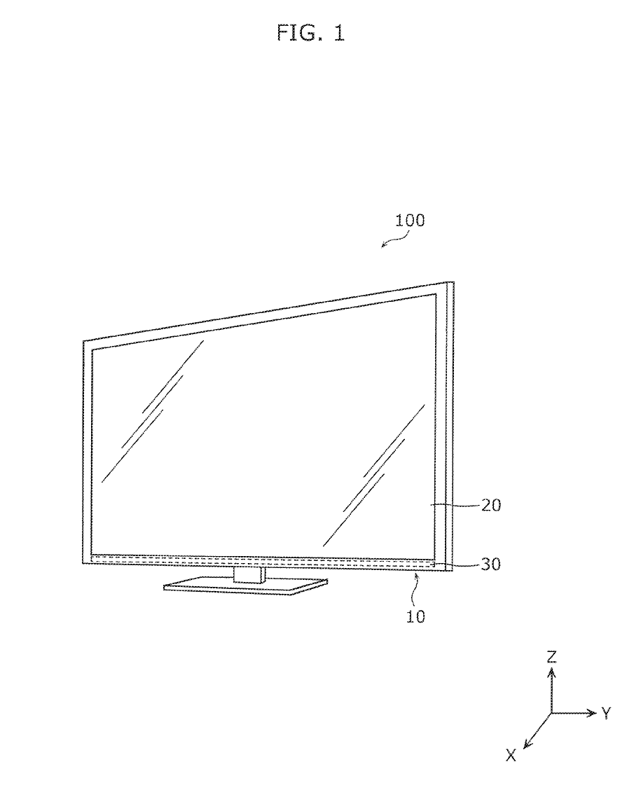

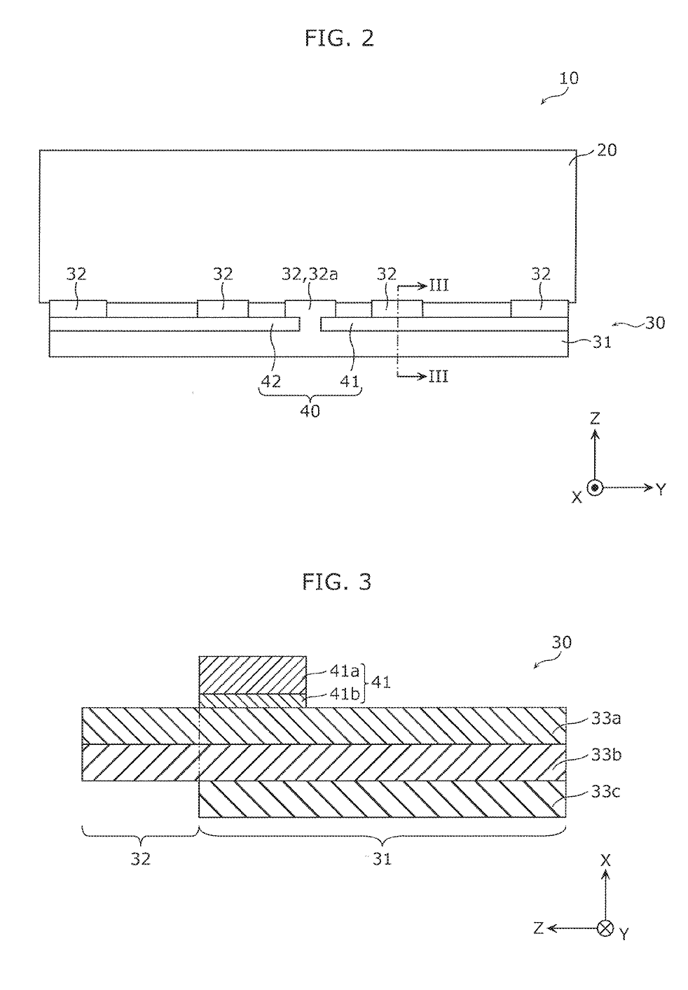

A configuration of a display module according to the present embodiment will be described with reference to FIGS. 1 and 2.

FIG. 1 is a perspective view illustrating one example of a display device 100 including a display module 10 according to the present embodiment. FIG. 2 is a schematic view illustrating a configuration of the display module 10 according to the present embodiment. For simplification, the display modules 10 in (a) and (b) of FIG. 2 and the display module 10 illustrated in FIG. 1 are illustrated on different scales. The same also applies to the drawings below.

As illustrated in FIG. 1, the display device 100 including the display module 10 according to the present embodiment is, for example, a thin-profile display apparatus for television which displays images. The display device 100 can display any image. The image may be a moving picture, or may be a still picture. The image may include characters and/or numerals.

As illustrated in FIG. 2, the display module 10 includes a display panel 20 and a flexible wiring plate 30. Hereinafter, the flexible wiring plate 30 is also simply referred to as wiring plate 30. Although FIG. 2 illustrates an example in which the display module includes a single wiring plate 30, the display module 10 may include a plurality of wiring plates 30.

The components included in the display module 10 will now be described with reference to the drawings when necessary.

### [1-1-1. Display Panel]

The display panel 20 will be described with reference to FIG. 2.

The display panel 20 displays images. The display panel 20 is implemented with an organic EL panel or a liquid crystal panel, for example. In the case where the display panel 20 is a liquid crystal panel, the display module 10 may include a light source having a plurality of light emitting diodes (LEDs).

Although not illustrated, a source driver and a gate driver may be packaged in the display panel 20. In other words, the display panel 20 may be a Chip-On-Glass (COG) packaged display panel.

The display panel 20 can have any size, and is about 20 inches as one example. The display panel 20 can include any substrate. The substrate may be a glass substrate, or may be a plastic substrate. The substrate may have flexibility.

### [1-1-2. Wiring Plate]

The wiring plate 30 will be described with reference to FIG. 2. As illustrated in FIG. 2, the feature of the wiring plate 30 according to the present embodiment is that the wiring plate 30 includes a reinforcement member 40 as a shape retention structure. The detail of the reinforcement member 40 will be described later.

The wiring plate 30 is a flexible substrate which electrically connects the display panel 20 to an external circuit (not illustrated).

The wiring plate 30 includes an elongated body 31, and a plurality of connections 32 having connection terminals to be connected to the display panel 20, the connection terminals extending, in a shape of a narrow elongation, from one end of the body 31 in the lateral direction of the body 31 (in other words, in the direction intersecting substantially perpendicular to the longitudinal direction). In the present embodiment, an example in which five connections 32 are disposed is illustrated. Hereinafter, in the case where the same features of individual connections in the plurality of connections 32 will be described, the plurality of connections 32 is simply referred to as connection(s) 32. In the plurality of connections 32, at least one connection has the connection terminal to be connected to the display panel 20.

The body 31 includes a wiring pattern for electrically connecting the display panel 20 to an external circuit. In a plan view, the body 31 has an elongated shape, as one example, a rectangular shape. The body 31 includes the connections 32 for connecting to the display panel 20 at one end of the body 31 in the direction intersecting substantially perpendicular to the longitudinal direction (the end on the plus side of the Z-axis). The term “end” includes an end of the body 31 and its peripheral portion in a plan view.

For example, the body 31 has a width (length in the Y-axis direction) of 2.8 cm as one example, and has a length (length in the X-axis direction) of 37 cm as one example. The body 31 can have any size.

The connections 32 are projected from the edge of one end of the body 31 in the lateral direction (the edge of one end of the plus side of the Z-axis). In the present embodiment, the connections 32 extend, in a shape of a narrow elongation, from the body 31 toward the display panel 20. The term “shape of a narrow elongation” indicates that the connections 32 are disposed to extend with a width (a length in the Y-axis direction) smaller than the width (the length in the Y-axis direction) of the edge of the one end of the body 31. In other words, the connections 32 are projected from part of the edge of the one end of the body 31 in the lateral direction. Each of the connections 32 can have any width. The connections 32 may have an identical width, or may have different widths. In this specification, the term “identical” includes not only cases where items completely coincide with each other, but also cases where items are substantially equal. For example, two numeric values having an error of several percent, such as production errors, may be considered identical.

Although the details will be described later, among the five connections 32, the connection 32 disposed in the center of the body 31 in the longitudinal direction is a connection having an alignment mark used for positioning to the display panel 20, and is also referred to as reference connection 32a below. The reference connection 32a does not need to have a connection terminal. In the present embodiment, an example will be described in which the reference connection 32a has no connection terminal for connecting to the display panel 20.

In a plan view, among the edges of the ends of the wiring plate in the longitudinal direction (edges of the ends on the plus side of the Y-axis and the minus side of the Y-axis) and the edges of the ends thereof in the lateral direction (edges of the ends on the plus side of the Z-axis and the minus side of the Z-axis), the wiring plate 30 is disposed such that the edge of the one end of the wiring plate 30 in the lateral direction faces the edge of one end of the display panel 20. For example, in a plan view, the wiring plate 30 is disposed in the display panel 20 such that the edge of one end of a rectangular display panel 20 (such as the edge of the end of the minus side of the Z-axis) faces the edge of one end of the wiring plate 30 in the lateral direction (such as the edge of the end on the plus side of the Z-axis). In the present embodiment, the wiring plate 30 is disposed in the display panel 20 such that the edge of one end of the rectangular display panel 20 in the lateral direction (such as the edge of the end on the minus side of the Z-axis) faces the edge of one end of the body 31 of the wiring plate 30 in the lateral direction.

### [1-1-3. Reinforcement Member]

The reinforcement member 40 will be described with reference to FIG. 2.

The reinforcement member 40 is a reinforcement member for preventing warp of the wiring plate 30 at the ends in the longitudinal direction thereof in a lateral view of the wiring plate 30 when the wiring plate 30 is lifted up. In other words, the reinforcement member 40 prevents the ends of the wiring plate 30 in the longitudinal direction from deforming toward the minus direction of the X-axis. Accordingly, the reinforcement member 40 enhances the rigidity of the wiring plate 30.

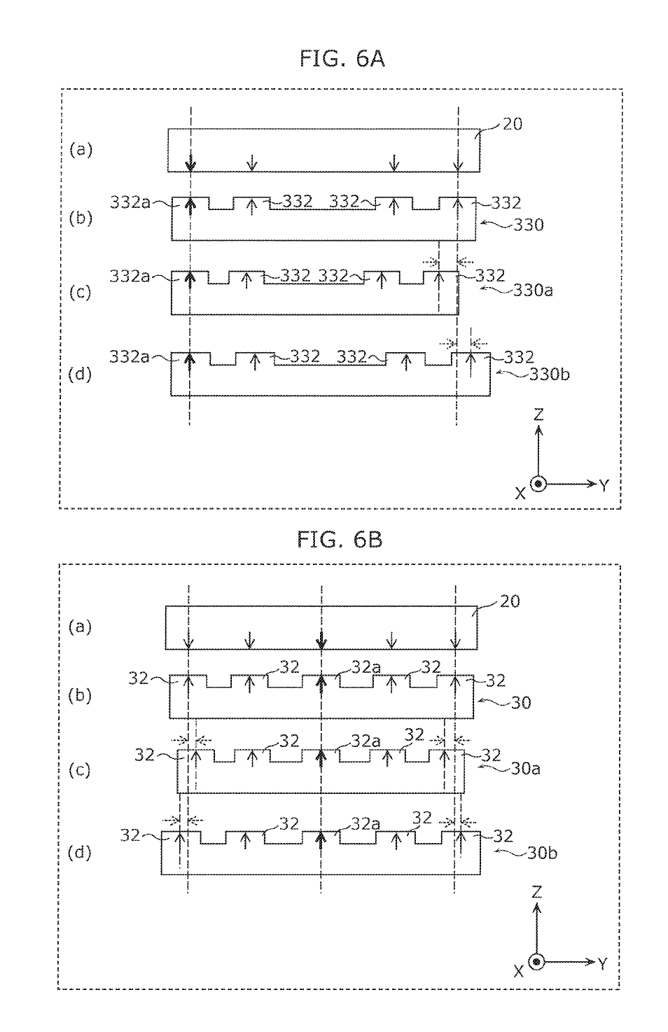

A wiring plate 30 without the reinforcement member 40 can be freely bent. For this reason, such a wiring plate warps when lifted up. For example, in the case where the wiring plate 30 without the reinforcement member 40 is held at two places and lifted up, the end portions of the wiring plate 30 in the longitudinal direction which are located on the outer sides of the holding positions of the wiring plate curve downward (for example, in the minus direction of the X-axis) (see FIG. 5B). In contrast, the reinforcement member 40 is disposed to enhance the rigidity of the wiring plate 30. Such a configuration prevents the warp of the wiring plate 30 at the ends in the longitudinal direction thereof in a lateral view of the wiring plate when the wiring plate 30 is lifted up.

As illustrated in FIG. 2, the reinforcement member 40 includes a first reinforcement member 41 and a second reinforcement member 42.

In a plan view, the first reinforcement member 41 is disposed from an end of the body 31 in the longitudinal direction (the end on the plus side of the Y-axis, which is one example of one end) to a portion close to the center of the body 31 in the longitudinal direction. Specifically, in the plan view, the first reinforcement member 41 is disposed from the edge of one end of the body 31 in the longitudinal direction (the edge of the end on the plus side of the Y-axis).

In the plan view, the second reinforcement member 42 is disposed from the end opposite to the one end of the body 31 in the longitudinal direction end (the end on the minus side of the Y-axis, which is one example of the other end) to a portion close to the center of the body 31 in the longitudinal direction. Specifically, in the plan view, the second reinforcement member 42 is disposed from the edge of the other end of the body 31 in the longitudinal direction (the edge of the end opposite to the one end, and also the edge of the end on the minus side of the Y-axis).

In a plan view, the first reinforcement member 41 and the second reinforcement member 42 have elongated shapes, and the longitudinal direction of the first reinforcement member 41 and that of the second reinforcement member 42 are substantially parallel to the longitudinal direction of the body 31. For example, the first reinforcement member 41 and the second reinforcement member 42 are plate-like members. In the plan view, the first reinforcement member 41 does not overlap with the second reinforcement member 42. In other words, the reinforcement member 40 is not disposed near the central portion of the body 31 in the longitudinal direction. Such a configuration can reduce the amount of the reinforcement member 40 to be used because the reinforcement member 40 is not disposed near the central portion of the body 31.

It should be noted that any other configuration than the configuration without the reinforcement member 40 near the central portion of the body 31 in the longitudinal direction can be used. The reinforcement member 40 may also be disposed near the central portion of the wiring plate 30 to further improve the rigidity of the wiring plate 30. For example, the reinforcement member 40 may be disposed as a single member extending from one end to the other end of the wiring plate 30. Alternatively, the reinforcement member may include a third reinforcement member (not illustrated) which is different from the first reinforcement member 41 and the second reinforcement member 42, and is disposed near the central portion of the body 31 in the longitudinal direction, thereby further enhancing the rigidity of the wiring plate 30.

Although an example in which the first reinforcement member 41 and the second reinforcement member 42 have rectangular outer shapes is illustrated in FIG. 2, the first reinforcement member 41 and the second reinforcement member 42 can have any other outer shapes. For example, the first reinforcement member 41 and the second reinforcement member 42 may have an oval shape, or may have a trapezoidal shape. The outer shapes of the first reinforcement member 41 and the second reinforcement member 42 may be identical, or may be different.

The first reinforcement member 41 and the second reinforcement member 42 have lengths (the lengths in the Z-axis direction) smaller than the length (the length in the Z-axis direction) of the body 31. In other words, in a plan view, the first reinforcement member 41 and the second reinforcement member 42 are not disposed across the entire body 31. As one example, the first reinforcement member 41 and the second reinforcement member 42 have lengths not longer than 2.8 cm (i.e., the length of the body 31, and as one example, about ⅓ of the length of the body 31.

The positioning of the display panel 20 and the wiring plate 30 is performed using the alignment marks disposed in the connections 32 and the alignment marks disposed in the display panel 20, for example. The curving of the connections 32 during the lifting up of the wiring plate 30 leads to difficulties in positioning. Accordingly, for easier positioning, it is desired that the connections 32 barely warp when the wiring plate 30 is lifted up. For this reason, in a plan view, the first reinforcement member 41 and the second reinforcement member 42 are disposed at the one end of the body 31 to be connected to the display panel 20 (the end on the plus side of the Z-axis, which is one example of the one end) among the ends of the body 31 in the lateral direction.

Compared to the case where the first reinforcement member 41 and the second reinforcement member 42 are disposed at the other end opposite to the one end of the body 31, such a configuration can prevent the warp of the connections 32 and the body 31 on the side of connections 32. In a plan view, the connections 32 are not disposed in the first reinforcement member 41 and the second reinforcement member 42. In other words, in a plan view, the first reinforcement member 41 and the second reinforcement member 42 are disposed at the positions not overlapping with the connection terminal.

Although an example in which the first reinforcement member 41 and the second reinforcement member 42 are disposed such that the longitudinal direction of the body 31 is substantially parallel to the longitudinal direction of the first reinforcement member 41 and that of the second reinforcement member 42 has been described in FIG. 2, any other configuration can be used. For example, the first reinforcement member 41 and the second reinforcement member 42 may be disposed such that the longitudinal direction of the first reinforcement member 41 and that of the second reinforcement member 42 each form a predetermined angle with the longitudinal direction of the body 31.

Although an example in which the reinforcement member 40 includes the first reinforcement member 41 and the second reinforcement member 42 has been described, any other configuration can be used. For example, the reinforcement member may include only one of the first reinforcement member 41 and the second reinforcement member 42. In other words, the reinforcement member 40 may be disposed in a region including a side containing at least one of the one end and the other end of the body 31 in the longitudinal direction.

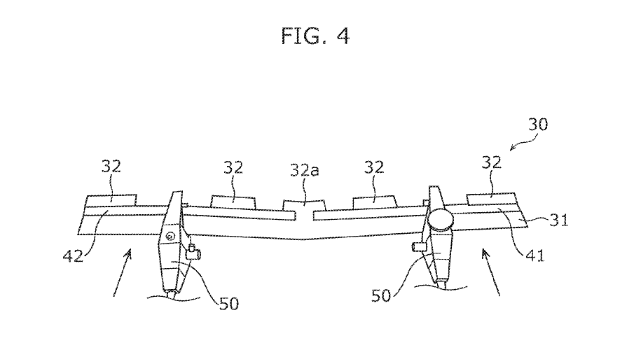

The wiring plate 30 and the reinforcement member 40 will now be described more in detail with reference to FIG. 3.

FIG. 3 is a sectional view illustrating the wiring plate 30 according to the present embodiment, which is taken along the III-III line in FIG. 2. In FIG. 3, a sectional view of the first reinforcement member 41 as the reinforcement member 40 will be described. The same also applies to the second reinforcement member 42.

As illustrated in FIG. 3, the body 31 includes a laminate of a substrate layer 33a (base film) made of a resin material, an electroconductive layer 33b having an electroconductive member made of a metal, and a substrate layer 33c (cover film) made of a resin material. The substrate layer 33a is bonded to the electroconductive layer 33b with an adhesive layer (not illustrated). The electroconductive layer 33b is bonded to the substrate layer 33c with an adhesive layer (not illustrated). The substrate layers 33a and 33c are insulation films having flexibility, such as polyimide. The electroconductive layer 33b is, for example, a metal foil, a laminate of metal foils, or a metal foil having a surface covered with solder. The metal foil and the wirings are made of Cu or Ag, for example. The substrate layer 33a is an insulation layer disposed on the surface of the wiring plate 30.

The connection 32 is disposed as a laminate of the substrate layer 33a and the electroconductive layer 33b. The electroconductive layer 33b on the minus side of the X-axis is exposed. The electroconductive layer 33b exposed from the connection 32 is one example of a connection terminal. The connection terminal may be plated with nickel or gold.

The substrate layer 33a has a thickness of 25 μm as one example. The electroconductive layer 33b has a thickness of 20 μm as one example. The substrate layer 33c has a thickness of 13 μm as one example.

Although the wiring plate 30 having a one-sided structure is illustrated in FIG. 3, the wiring plate 30 can have any layer structure. For example, the wiring plate 30 may have a double-sided structure, or may have a multi-layer structure having a combination of a one-sided structure and a double-sided structure.

The first reinforcement member 41 is composed of a laminate of a substrate layer 41a and an adhesive layer 41b.

The substrate layer 41a contains a resin material, for example. For example, the substrate layer 41a contains polyimide. In other words, the substrate layer 41a may be made of the same resin material as that for the substrate layers 33a and 33c. Thereby, the first reinforcement member 41 (the reinforcement member 40) can be achieved by using the material conventionally used for the flexible substrates. Compared to the case where only the substrate layers 33a and 33c are disposed, the total thickness of the resin layers is increased by the thickness of the substrate layer 41a even when the substrate layers 33a, 33c, and 41a are made of the same resin material. As a result, the wiring plate 30 has an increased rigidity. The substrate layer 41a has a thickness of 225 μm as one example.

The substrate layer 41a can be made of any material other than the material described above, and can be made of a material having a rigidity higher than those of the substrate layers 33a and 33c. For example, the substrate layer 41a may be made of a hard material such as Flame Retardant Type 4 (FR4). In this case, the substrate layer 41a can have a thickness smaller than that of the substrate layer 41a made of polyimide.

The adhesive layer 41b is an adhesive which bonds the substrate layers 33a and 41a to each other. An epoxy, acrylic, or polyimide adhesive is used. In other words, the first reinforcement member 41 is bonded to the body 31 with the adhesive layer 41b. The adhesive layer 41b has a thickness of 50 μm as one example.

Such a first reinforcement member 41 can be achieved using a reinforcing plate, for example.

As illustrated in FIG. 3, the first reinforcement member 41 is bonded onto the substrate layer 33a. In other words, the first reinforcement member 41 is bonded onto the surface (the surface on the plus side of the X-axis) of the body 31.

As described above, the wiring plate 30 according to the present embodiment has a shape retention structure, that is, the wiring plate 30 further includes the reinforcement member 40 disposed on the surface of the body 31 including the substrate layers 33a and 33c, and the electroconductive layer 33b.

Although an example in which the first reinforcement member 41 is disposed on the substrate layer 33a is illustrated in FIG. 3, any other configuration can be used. For example, the first reinforcement member 41 may be disposed on the substrate layer 33c (on the surface of substrate layer 33c on the minus side of the X-axis in FIG. 3).

Although not illustrated, the wiring plate 30 may include an electronic component for processing signals for displaying images, such as an IC chip or a connector. As illustrated in FIG. 3, any electronic component is not mounted on the region of the substrate layer 33c, which is located below the first reinforcement member 41 (on the minus side of the X-axis). In other words, when the electronic component is mounted on the wiring plate 30, in a plan view of the wiring plate 30, the reinforcement member 40 and the electronic component are disposed at the positions such that the reinforcement member 40 does not overlap with the electronic component.

[1-2. State that Wiring Plate is Lifted Up]

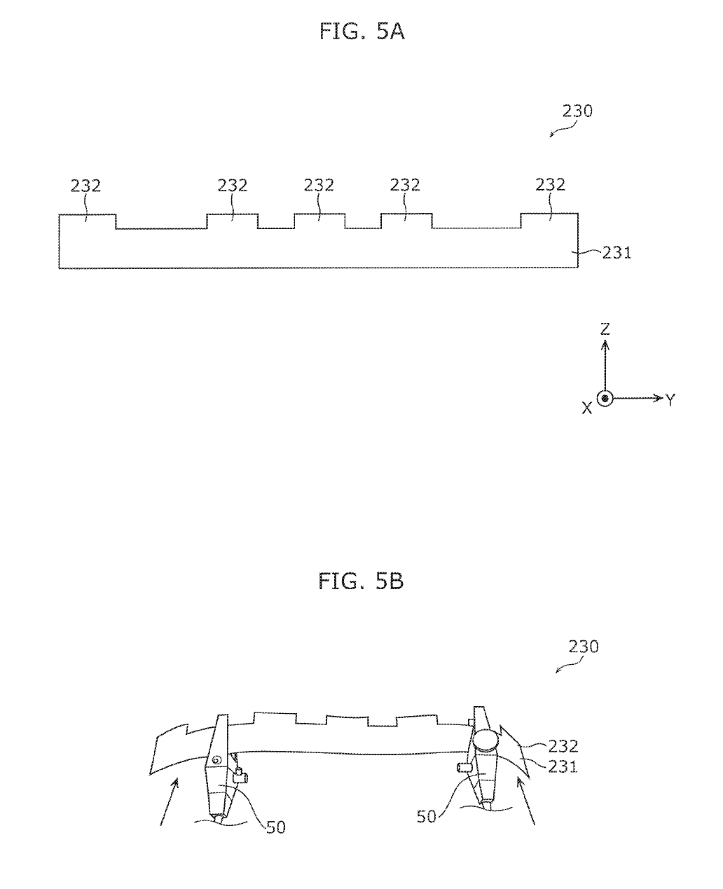

A state where the wiring plate 30 including the reinforcement member 40 described above is lifted up will be described with reference to FIGS. 4 to 5B. The state will be described based on the comparison with a wiring plate 230 not including a reinforcement member 40

FIG. 4 is a diagram illustrating a state where the wiring plate according to the present embodiment is lifted up. FIG. 5A is a schematic view illustrating a configuration of a wiring plate 230 according to Comparative Example 1. FIG. 5B is a diagram illustrating a state where the wiring plate 230 according to Comparative Example 1 is lifted up.

As illustrated in FIG. 4, it is found that when the wiring plate according to the present embodiment is lifted up with two arms 50, one end and the other end (see the arrows in the drawing) of the wiring plate 30 in the longitudinal direction are not curved downward.

In contrast, it is found that in the case where the wiring plate 230 including a body 231 and connections 232 but not including the reinforcement member 40 as illustrated in FIG. 5A is lifted up, as illustrated in FIG. 5B, one end and the other end (see the arrows in the drawing) of the wiring plate 230 in the longitudinal direction are curved downward. Specifically, the wiring plate 230 is curved in the regions ranging from the positions held with the two arms 50 toward the edge of the one end and the edge of the other end of the wiring plate 230.

The reinforcement member 40 is disposed at least from the edge of the one end of the wiring plate 30 in the longitudinal direction to the position thereof held with the arm 50. In other words, the term “reinforcement member 40 is disposed in the end in the longitudinal direction” used in this specification indicates that the reinforcement member 40 is disposed at least from the edge of one end of the wiring plate 30 in the longitudinal direction to the position thereof held with the arm 50.

For example, the first reinforcement member 41 and the second reinforcement member 42 have at least widths (the lengths in the Y-axis direction) larger than the distance between the connection 32 disposed at one end and its adjacent connection 32 disposed closer to the center of the wiring plate 30 than the connection 32 disposed at the one end. The distance is a distance connecting the two edges of the connections 32 on the plus side of the Y-axis in the direction parallel to the Y-axis direction, for example. The first reinforcement member 41 and the second reinforcement member 42 are disposed from the edge of one end and the edge of the other end of the body 31 in the longitudinal direction, respectively. Thereby, the first reinforcement member 41 and the second reinforcement member 42 are disposed to the positions of the body 31 from which the adjacent connection 32 disposed closer to the center of the wiring plate than the connection 32 disposed at the one end are projected, respectively. The first reinforcement member 41 and the second reinforcement member 42 thus formed have widths (the lengths in the Y-axis direction) larger than the width (the length in the Y-axis direction) of the connection 32.

### [1-3. Positioning]

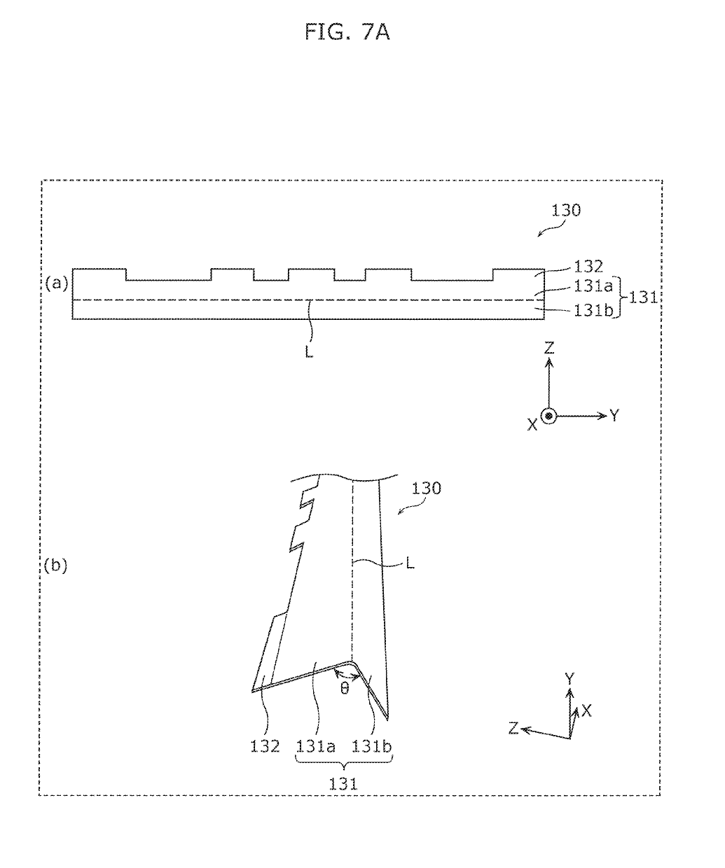

The positioning when the wiring plate 30 including the reinforcement member 40 above is press bonded to the display panel will be described with reference to the FIGS. 6A and 6B. As described above, the wiring plate 30 according to the present embodiment includes a reference connection 32a near the central portion of the wiring plate 30 in the longitudinal direction. The positioning of the wiring plate 30 will now be described below in comparison with a wiring plate including a reference connection near one end of the wiring plate in the longitudinal direction. Here, the prevention of the deviation of the press bonding position for each connection will be described in the case where the deviation is caused by a fluctuation in size of the wiring plate during manufacturing the wiring plate.

The deviation of the press bonding position of the wiring plate including the reference connection near the one end of the wiring plate in the longitudinal direction will now be described with reference to FIG. 6A.

FIG. 6A is a schematic view illustrating the press bonding positions of a wiring plate 330 according to Comparative Example 2, which vary according to the size of the wiring plate 330. Specifically, (a) of FIG. 6A is a diagram illustrating a display panel 20, (b) of FIG. 6A is a diagram illustrating the press bonding positions of the wiring plate 330 produced to have a size according to the designed values, (c) of FIG. 6A is a diagram illustrating a wiring plate 330a produced to have a size smaller than the designed values, and (d) of FIG. 6A is a diagram illustrating a wiring plate 330b produced to have a size larger than the designed values.

In the drawings, the arrows with a solid line indicate the positions of the display panel 20 and their corresponding positions of the connection 332. It is desired that the display panel 20 be press bonded to the wiring plate 330 such that the four arrows of the display panel 20 substantially correspond to the four arrows of the wiring plate 330, that is, the deviation of the press bonding position of the display panel 20 to the wiring plate 330 be minimized.

The term “size larger or smaller than the designed values” herein indicates that the length in the Y-axis direction is larger or smaller than a predetermined length. The same also applies below.

In the case where the display panel 20 is press bonded to the wiring plate 330, the positioning of the display panel 20 and the wiring plate 330 is performed, followed by temporary bonding (temporary press bonding). After the temporary bonding, main press bonding is performed to press bond the display panel 20 to the wiring plate 330. The precision in the temporary bonding results in the precision of the press bonding position (connection precision) of the display panel 20 and the wiring plate 330.

In the wiring plate 330 according to Comparative Example 2, an alignment mark for positioning to the display panel 20 is disposed in the connections 332 projected from the end of the wiring plate 330 on the minus side of the Y-axis. In other words, the connection 332 projected from the end of the wiring plate 330 on the minus side of the Y-axis is the reference connection 332a.

In the case where the wiring plate 330 according to Comparative Example 2 is used, the positioning to the display panel is performed using the reference connection 332a disposed on the minus side of the Y-axis. In (a) to (d) of the drawing, the reference connection 332a is represented by the arrow with a bold solid line.

As illustrated in (b) of FIG. 6A, the wiring plate 330 has a size according to the designed values. For this reason, the positioning with precision can be performed in the case where the reference connection 332a is used to perform the positioning.

In contrast, as illustrated in (c) and (d) of FIG. 6A, a wiring plate 330 having a size larger or smaller than the designed values causes the positional deviation between the display panel 20 and the connections 332 to be temporarily bonded. In other words, the wiring plate 330 according to Comparative Example 2 will cause a deviation of the press bonding position. The deviation of the press bonding position will now be described using the connection 332 projected from the other end (the end on the plus side of the Y-axis) opposite to the end at which the reference connection 332a is disposed, i.e., the connection 332 having the largest deviation.

For example, as illustrated in (c) of FIG. 6A, the temporary bonding of the reference connection 332a to the display panel 20 is performed with precision by positioning the wiring plate 330a having a size smaller than the designed values using the reference connection 332a. In contrast, the deviation of the temporary bonding position occurs (see the arrows with a dashed line) in the connection 332 projected from the other end (the end on the plus side of the Y-axis) opposite to the end at which the reference connection 332a is disposed. In other words, the deviation of the press bonding position of the connections 332 to the display panel 20 occurs at the end on the plus side of the Y-axis.

Similarly, also in the case where the wiring plate 330b having a size larger than the designed values is positioned using the reference connection 332a, as illustrated in (d) of FIG. 6A, the deviation of the temporary bonding position occurs (see the arrows with a dashed line) in the connection 332 projected from the other end (the end on the plus side of the Y-axis) opposite to the end at which the reference connection 332a is disposed. In other words, the deviation of the press bonding position of the connections 332 to the display panel 20 occurs at the end on the plus side of the Y-axis.

As described above, in the case where the reference connection 332a is disposed at the one end of the wiring plate 330, the positioning of the connection 332 disposed at the other end opposite to the end at which the reference connection 332a is disposed is readily affected by the fluctuation in size of the wiring plate 330, resulting in an increased deviation of the press bonding position.

In contrast, in the wiring plate 30 according to the present embodiment, an alignment mark for positioning to the display panel is disposed in the connection 32 projected from the position closest to the center of the wiring plate 30 in the longitudinal direction. The connection 32 projected from the position closest to the center of the wiring plate 30 in the longitudinal direction is the reference connection 32a. The deviation of the press bonding position in this case will be described with reference to FIG. 6B. The reference connection 32a can be disposed at any position in the longitudinal direction of the wiring plate 30 other than the position closest to the center of the wiring plate 30 in the longitudinal direction among the plurality of connections 32. For example, the reference connection 32a is disposed at least in any position other than the positions of the endmost connections 32 in the longitudinal direction of the wiring plate 30.

FIG. 6B is a schematic view illustrating the press bonding positions of the wiring plate 30 according to the present embodiment, which vary according to the size of the wiring plate 30. Specifically, (a) of FIG. 6B is a diagram illustrating a display panel 20, (b) of FIG. 6B is a diagram illustrating a wiring plate 30 produced to have a size according to the designed values, (c) of FIG. 6B is a diagram illustrating a wiring plate 30a produced to have a size smaller than the designed values, and (d) of FIG. 6B is a diagram illustrating a wiring plate 30b produced to have a size larger than the designed values. In the drawing, the arrows with a solid line indicate the positions of the display panel 20 and their corresponding positions of the connections 32. It is desired that the display panel 20 be press bonded to the wiring plate 30 such that the four arrows of the display panel 20 substantially correspond to the four arrows of the wiring plate 30, in other words, the deviation of the press bonding position of the display panel 20 to the wiring plate 30 be minimized. In FIG. 6B, the reinforcement member 40 is omitted.

In the case where the display panel 20 is press bonded to the wiring plate 30, the positioning of the display panel 20 and the wiring plate 30 is performed, followed by the temporary bonding (temporary press bonding). In the wiring plate 30 according to the present embodiment, the connection 32 projected from substantially the center of the wiring plate 30 in the longitudinal direction is the reference connection 32a. In other words, in the case where the wiring plate 30 according to the present embodiment is used, the positioning to the display panel 20 is performed using the reference connection 32a disposed substantially the center of the wiring plate in the longitudinal direction.

As illustrated in (b) of FIG. 6B, the wiring plate 30 has a size according to the designed values. For this reason, the positioning with precision can be performed in the case where the reference connection 32a is used to perform the positioning.

As illustrated in (c) and (d) of FIG. 6B, it is found that although a deviation of the temporary bonding position of the display panel 20 to the connections 32 is caused by the wiring plate 30 having a size smaller or larger than the designed values, the amount of deviation is smaller than those in (c) and (d) of FIG. 6A. In other words, the wiring plate 30 according to the present embodiment can reduce the amount of deviation of the press bonding position caused by the fluctuation in size of the wiring plate 30.

For example, as illustrated in (c) of FIG. 6B, the temporary bonding of the reference connection 32a to the display panel 20 is performed with precision by positioning the wiring plate 30a having a size smaller than the designed values using the reference connection 32a. Furthermore, although the deviation of the temporary bonding position occurs in the connection 32 projected from the ends of the wiring plate 30 in the longitudinal direction, the amount of deviation is smaller than that in (c) of FIG. 6A.

Similarly, also in the case where the wiring plate 30b having a size larger than the designed values is positioned using the reference connection 32a, as illustrated in (d) of FIG. 6B, the amount of deviation is smaller than that in (d) of FIG. 6A although the deviation of the temporary bonding position occurs in the connection 32 projected from the ends of the wiring plate 30 in the longitudinal direction.

As described above, in the wiring plate 30 according to the present embodiment, the reference connection 32a is disposed substantially in the central portion of the wiring plate 30. Thereby, the influences of the fluctuation in size of the wiring plate 30, if any, can be averaged, compared to the wiring plate 330 according to Comparative Example 2. For this reason, the precision of the temporary bonding positions of the wiring plate 30 at the two ends thereof in the longitudinal direction can be improved. In other words, the precision (connection precision) of the press bonding position of the display panel 20 to the wiring plate 30 can be improved.

### [1-4. Advantageous Effects]

As described above, the wiring plate 30 according to the present embodiment is an elongated flexible wiring plate to be connected to the display panel 20. The wiring plate 30 includes a shape retention structure to prevent the warp of the wiring plate 30 at the ends thereof in the longitudinal direction in a lateral view of the wiring plate 30.

Such a configuration of the wiring plate 30 including a shape retention structure can prevent the warp of the wiring plate 30 at the ends thereof in the longitudinal direction. For example, in the case where the wiring plate 30 includes the reinforcement member 40 as a shape retention structure, the reinforcement member 40 enhances the rigidity of the wiring plate 30, thereby preventing the warp of the wiring plate 30 at the ends thereof in the longitudinal direction. In other words, the wiring plate 30 can reduce the difficulties in positioning to the display panel 20, which are caused by the warp of the wiring plate 30. Accordingly, the wiring plate 30 according to the present embodiment more significantly facilitates the positioning to the display panel 20, compared to the wiring plates in the related art.

The wiring plate 30 includes the reinforcement member 40 as a shape retention structure disposed on the surface of the wiring plate 30. In a plan view of the wiring plate 30, the reinforcement member 40 is disposed at the ends of the wiring plate 30 in the longitudinal direction.

Thereby, the wiring plate 30 includes the reinforcement member 40 at the ends of the wiring plate 30 in the longitudinal direction, increasing the rigidity at the ends of the wiring plate 30 in the longitudinal direction. In other words, the warp of the wiring plate 30 at the ends thereof in the longitudinal direction can be prevented. Accordingly, even in the case of a large-sized wiring plate 30, the warp of the wiring plate 30 can be prevented during the positioning to the display panel 20, thereby facilitating the positioning to the display panel 20.

In a plan view of the wiring plate 30, the reinforcement member 40 has an elongated shape extending in the longitudinal direction of the wiring plate 30.

Thereby, the reinforcement member 40 is disposed so as to extend in the same direction as that of the body 31 of the wiring plate 30. The ends of the wiring plate 30 in the extending direction of the wiring plate 30 (in the longitudinal direction of the wring plate 30) are readily curved. In other words, the rigidity of the wiring plate 30 can be effectively improved by the reinforcement member 40 which extends in the same direction as that of the wiring plate 30.

The reinforcement member 40 includes the first reinforcement member 41 and the second reinforcement member 42. The first reinforcement member 41 is disposed at one end of the wiring plate in the longitudinal direction (for example, the end on the plus side of the Y-axis in the longitudinal direction), and the second reinforcement member 42 is disposed at the other end of the wiring plate 30 in the longitudinal direction (for example, the end on the minus side of the Y-axis in the longitudinal direction).

Thereby, the reinforcement member 40 is disposed at both ends of the wiring plate 30 in the longitudinal direction. In other words, the warp of the wiring plate 30 at the two ends thereof in the longitudinal direction can be prevented.

In a plan view of the wiring plate 30, the reinforcement member 40 is disposed on one end side to be connected to the display panel 20 (for example, the end side in the plus direction of the Z-axis) among the ends of the wiring plate 30 in the lateral direction.

Thereby, the warp of the one end of the wiring plate 30 to be connected to the display panel 20 (the end on the plus side of the Z-axis) can be prevented. The positioning of the wiring plate 30 to the display panel 20 can be more significantly facilitated because the end of the wiring plate 30 to be connected to the display panel 20 barely warps.

The connection terminal to be connected to the display panel is disposed on the one end side of the wiring plate 30. In a plan view of the wiring plate 30, the reinforcement member 40 is disposed at a position not overlapping with the connection terminal.

Such a configuration can reduce the influences by the reinforcement member 40 during the press bonding of the wiring plate 30 to the display panel 20. The wiring plate 30 is connected to the display panel 20 by thermal press bonding using an ACF, for example. The reinforcement member 40 disposed at a position not overlapping with the connection terminal can prevent the reinforcement member 40 from obstructing the heat conduction to the ACF. In a plan view of the wiring plate 30, the reinforcement member 40 is disposed in a position not overlapping with the connection terminal. For this reason, the wiring plate 30 press bonded to the display panel 20 is readily bent to the side of the non-display surface of the display panel 20 (the surface of the display panel 20 on the minus side of the X-axis). In such a configuration, the portions including the connection terminals of the wiring plate 30 have an increased rigidity when the wiring plate 30 is fixed to the non-display surface of the display panel 20, thus preventing a reduction in workability in an operation to bend the wiring plate 30. Accordingly, in a plan view of the wiring plate 30, the reinforcement member 40 disposed in a position not overlapping with the connection terminal can enhance the rigidity of the wiring plate 30 while preventing a reduction in workability in the operation to bend the wiring plate 30.

The wiring plate 30 includes the elongated body 31, and the plurality of connections 32 extending from one end of the body 31 in the lateral direction, and at least one of the connections 32 has a connection terminal to be connected to the display panel 20. Among the plurality of connections 32, the reference connection 32a disposed at a position closest to the center of the wiring plate 30 in the longitudinal direction has an alignment mark for positioning to the display panel 20.

Accordingly, the positioning of the wiring plate 30 to the display panel 20 during the press bonding can be performed using the alignment mark included in the reference connection 32a disposed at a position closest to the center of the wiring plate 30. Such a configuration can prevent the deviation of the press bonding position caused by a fluctuation in size of the wiring plate 30, compared to the case where the connection 32 disposed at one of the endmost positions of the wiring plate 30 is the reference connection 32a The reference connection 32a does not have any connection terminal.

Thereby, the reference connection 32a can be disposed independently of the wiring pattern of the connection terminal formed in the display panel 20. The importance of the positioning precision increases as the size of the wiring plate 30 increases. Accordingly, in a large-sized wiring plate 30, the reference connection 32a is disposed in a position closer to the central portion of the wiring plate 30 in the longitudinal direction. Such a configuration enables the positioning with precision even in such a large-sized wiring plate 30.

As described above, the display device 100 according to the present embodiment includes the display panel 20 and the wiring plate according to 30, which are described above.

Thereby, the display device 100 can be readily manufactured even when a large-sized wiring plate 30 is used.

### Embodiment 2

### [2-1. Configuration of Wiring Plate]

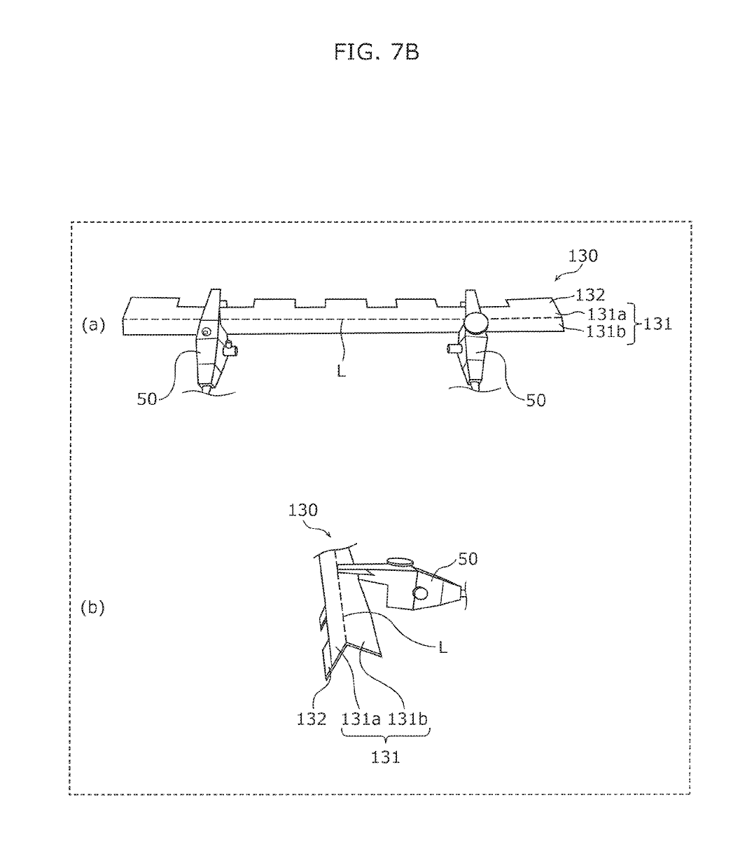

A configuration of the display module according to the present embodiment will be described with reference to FIG. 7A. In the present embodiment, the differences from Embodiment 1 will be mainly described.

FIG. 7A is a schematic view illustrating a configuration of a wiring plate 130 according to the present embodiment. Specifically, (a) of FIG. 7A is a plan view illustrating a configuration of the wiring plate 130 according to the present embodiment, and (b) of FIG. 7A is a perspective view illustrating the wiring plate 130 seen from the longitudinal direction of the wiring plate 130 according to the present embodiment. More specifically, (b) of FIG. 7A is a diagram illustrating the wiring plate 130 in a plan view when the end side on the minus side of the Y-axis of the wiring plate 130 is seen from the outer side in the longitudinal direction (when seen from the minus side of the Y-axis to the plus side of the Y-axis).

As illustrated in (a) and (b) of FIG. 7A, the wiring plate 130 according to the present embodiment includes a body 131 and a plurality of connections 132. The dashed lines illustrated in (a) and (b) of FIG. 7A both indicate a fold L. In other words, as a feature, the wiring plate 130 according to the present embodiment includes a body 131 having a bending structure as a shape retention structure. The bending structure will now be described.

As illustrated in (a) of FIG. 7A, the fold L in the present embodiment extends in the longitudinal direction of the wiring plate 130. In other words, the body 131 in the present embodiment is bent along the longitudinal direction of the wiring plate 130. In other words, the body 131 is bent to the lateral direction of the wiring plate 130. The fold L is formed by bending the body 131.

The body 131 includes a first body 131a and a second body 131b. In the body 131, the first body 131a is a region ranging from the fold L toward the connections 132 of the body 131. The first body 131a is not turned over when the body 131 is bent. In other words, the first body 131a and the connections 132 are positioned in the same plane. In the body 131, the second body 131b is a region ranging from the fold L to the side of the body 131 opposite to the connections 132. The second body 131b is turned over when the body 131 is bent. In other words, the second body 131b is not positioned in the same plane as the plane in which the first body 131a and the connections 132 are positioned. The bending structure is achieved by the first body 131a and the second body 131b. In other words, the bending structure in the present embodiment indicates the shape of the wiring plate 130 in a lateral view of the wiring plate 130 for preventing the warp of the wiring plate 130 at the ends thereof in the longitudinal direction when the wiring plate 130 is lifted up.

As illustrated in (b) of FIG. 7A, the wiring plate 130 is bent such that the top side (the plus side of the X-axis) is projected. In other words, in the present embodiment, the bending structure is formed by folding the body 131 into an inverted V-shape in the lateral direction of the body 131. The wiring plate 130 may be bent such that the bottom side (the minus side of the X-axis) is projected. In other words, the bending structure may be formed by folding the body 131 into a V-shape in the lateral direction of the body 131.

In the present embodiment, the bending structure is formed into a substantially V-shape seen in the longitudinal direction of the wiring plate 130. The first body 131a and the second body 131b can form any angle θ (see θ in (b) of FIG. 7A). The angle θ formed by the first body 131a and the second body 131b may be an acute angle, may be an obtuse angle, or may be 90°. The angle θ formed by the first body 131a and the second body 131b is an acute angle to enhance the rigidity. The angle θ formed by the first body 131a and the second body 131b is identical from the minus side of the Y-axis to the plus side of the Y-axis of the wiring plate 130.

The body 131 may be bent, for example, such that the length of the first body 131a (the length of the wiring plate 130 in the lateral direction) is shorter than the length of the second body 131b (the length of the wiring plate 130 in the lateral direction). The body 131 may be bent, for example, such that the length of the first body 131a and the length of the second body 131b are substantially constant in the longitudinal direction of the wiring plate 130. In this case, the fold L is formed so as to be substantially parallel to the longitudinal direction of the body 131.

The plurality of connections 132 is not bent.

[2-2. State where Wiring Plate is Lifted Up]

A state where the wiring plate 130 having the bending structure described above is lifted up will now be described with reference to FIG. 7B.

FIG. 7B is a diagram illustrating a state where the wiring plate 130 according to the present embodiment is lifted up. (a) of FIG. 7B is a diagram illustrating the wiring plate 130 lifted up in a plan view. (b) of FIG. 7B is a diagram illustrating the wiring plate 130 lifted up, seen from the longitudinal direction. To show the shape of the wiring plate 130 lifted up, (b) of FIG. 7B illustrates a state where the wiring plate 130 is lifted up with only the second body 131b held with the arm 50.

As illustrated in (a) and (b) of FIG. 7B, the wiring plate 130 having a bending structure can increase the rigidity of the wiring plate 130, and prevent the warp of the wiring plate 130 at the ends thereof in the longitudinal direction (specifically, the outer portions ranging from the positions of the wiring plate 130 held with the arms 50). In the present embodiment, the wiring plate 130 having enhanced rigidity can be manufactured by a simple method of bending a conventional wiring plate without any additional member.

### [2-3. Advantageous Effects]

As described above, the wiring plate 130 according to the present embodiment has a shape retention structure, which is a bending structure of the wiring plate 130 with the fold L formed so as to extend in the longitudinal direction of the wiring plate 130.

In such a configuration, using a simple method of bending the wiring plate 130, the rigidity of the wiring plate 130 can be enhanced without any additional member. Because the rigidity can be enhanced by bending the wiring plate, this method can also be used in the conventional wiring plates.

### OTHER EMBODIMENTS

Although the flexible wiring plate and the display device according to the present disclosure have been described based on the embodiments described above, these embodiments should not be construed as limitation to the flexible wiring plate and the display device according to the present disclosure. Other embodiments implemented with combinations of any components of the embodiments, a variety of modifications of the embodiments conceived and made by persons skilled in the art without departing from the gist of the present disclosure, and a variety of apparatuses and devices including the flexible wiring plate and the display device according to the present embodiment are also included in the present disclosure.

Although examples in which the connection terminal to be connected to the display panel is formed in the connection have been described in Embodiments 1 and 2 above, any other configuration can be used. For example, the connection terminal to be connected to the display panel may be disposed at one end of the body in the lateral direction. In this case, the connections projected from the body do not need to be disposed in the wiring plate.

Although examples in which a single reference connection is disposed in the wiring plate have been described in Embodiments 1 and 2 above, the wiring plate can include any number of reference connections. The wiring plate may include a plurality of reference connections. For example, the number of reference connections may be increased as the length of the wiring plate in the longitudinal direction increases. In other words, the positioning of the wiring plate to the display panel may be performed using a plurality of reference connections.

Although examples in which the wiring plate is held with a pair of arms and lifted up have been described in Embodiments 1 and 2 above, the wiring plate can be lifted up by any other method. For example, the wiring plate may be lifted up through adsorption of two places of the wiring plate, or may be lifted up by another method. In such a case where the wiring plate is lifted up through adsorption, the wiring plates described in Embodiments 1 and 2 above when lifted up through adsorption also exhibit the advantageous effects similar to those in the wiring plate held with the pair of arms and lifted up.

Although examples in which the connection having a connection terminal to be connected to the display panel is disposed at one end of the wiring plate in the lateral direction have been described in Embodiments 1 and 2 above, any other configuration can be used. For example, the connection having a connection terminal to be connected to the display panel may be disposed at one end of the wiring plate in the longitudinal direction. Also in this case, for example, the reinforcement member disposed so as to extend in the longitudinal direction of the wiring plate can prevent the warp of the wiring plate at the ends thereof in the longitudinal direction.

Although an example in which the reinforcement member has a two-layer structure composed of the substrate layer and the adhesive layer has been described in Embodiment 1 above, the reinforcement member can have any other configuration. For example, the reinforcement member may have a laminate structure of several substrate layers and several adhesive layers. The first reinforcement member and the second reinforcement member may have the same laminate structure, or may have different laminate structures.

Although an example in which the reinforcement member is not disposed in the connections has been described in Embodiment 1 above, any other configuration can be used. For example, a reinforcement member which prevents the warp of the connections may be disposed in the connections. In addition to the first reinforcement member and the second reinforcement member, the reinforcement member may include a fourth reinforcement member disposed in the connections.

Although an example in which the connection terminal is not disposed in the reference connection has been described in Embodiment 1 above, any other configuration can be used. The connection terminal to be connected to the display panel may be disposed in the reference connection. In other words, the reference connection may include the alignment mark for positioning to the display panel and the connection terminal for connecting to the display panel. Thereby, the reference connection can be disposed without increasing the number of connections.

Although an example in which the wiring plate is bent into a V shape seen from the longitudinal direction of the wiring plate has been described in Embodiment 2 above, the wiring plate can be bent into any other shape. For example, the wiring plate may have a Z shape, or may have any other shape seen from the longitudinal direction of the wiring plate. In other words, two or more folds may be formed in the body.

Although an example in which the fold is formed to be substantially parallel to the longitudinal direction (the Y-axis direction) of the body has been described in Embodiment 2 above, any other configuration can be used. The fold may be formed so as to have a predetermined angle formed with the longitudinal direction of the body. For example, the fold may be formed from the edge of one end in the longitudinal direction toward the end opposite to the connections of the body (the end on the minus side of the Z-axis) as the fold is applied toward the center of the longitudinal direction. Such a fold has a flared shape in a plan view, for example. In other words, the fold is formed only near the ends of the wiring plate in the longitudinal direction. Thereby, the rigidity of the target regions (the ends in the longitudinal direction) of the wiring plate can be effectively enhanced.

Although an example in which the second body in the body is turned over has been described in Embodiment 2 above, any other configuration can be used. At least one of the first body and the second body is turned over. The first body and the second body may be turned over in opposite directions seen from the longitudinal direction of the wiring plate.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is applicable to display devices including flexible wiring plates to be connected to display panels, and is particularly useful in display devices including large-sized display panels.

1. A flexible wiring plate which is elongated in a longitudinal direction of the flexible wiring plate and is to be connected to a display panel to be elongated along an edge of the display panel, the flexible wiring plate comprising:
a shape retention structure which prevents warp of the flexible wiring plate,
wherein the shape retention structure includes a first reinforcement member and a second reinforcement member provided on a major surface of the flexible wiring plate,
each of the first reinforcement member and the second reinforcement member has an elongated shape extending in a longitudinal direction of the flexible wiring plate,
the first reinforcement member is positioned at a first end of ends of the flexible wiring plate in the longitudinal direction,
the second reinforcement member is positioned at a second end of the ends of the flexible wiring plate in the longitudinal direction, the second end being opposite the first end in the longitudinal direction of the flexible wiring plate,
the first reinforcement member and the second reinforcement member are aligned in the longitudinal direction of the flexible wiring plate, and are spaced from one another in the longitudinal direction of the flexible wiring plate.

2-4. (canceled)

5. The flexible wiring plate according to claim 1,
wherein each of the first and second reinforcement members is positioned at an edge of the major surface of the flexible wiring plate, the edge being to be connected to the display panel.

6. The flexible wiring plate according to claim 5,
wherein a connection terminal to be connected to the display panel is provided at the edge of the major surface of the flexible wiring plate, and
the first and second reinforcement members do not overlap the connection terminal, when viewed from a direction perpendicular to the major surface of the flexible wiring plate.

7. (canceled)

8. The flexible wiring plate according to claim 1,
wherein the flexible wiring plate includes an elongated body, and a plurality of connections extending from an edge of the elongated body, the edge extending in the longitudinal direction of the flexible wiring plate,
at least one connection of the plurality of connections has a connection terminal to be connected to the display panel, and
among the plurality of connections, a reference connection disposed at a position closest to a center of the flexible wiring plate in the longitudinal direction has an alignment mark for positioning to the display panel.

9. The flexible wiring plate according to claim 8,
wherein the connection terminal is not provided in the reference connection.

10. A display device, comprising:
a display panel; and
the flexible wiring plate according to claim 1.

11. The flexible wiring plate according to claim 1, wherein
an end of the first reinforcement member in the longitudinal direction thereof matches the first end of the flexible wiring plate in the longitudinal direction thereof,
an end of the second reinforcement member in the longitudinal direction thereof matches the second end of the flexible wiring plate in the longitudinal direction.

12. The flexible wiring plate according to claim 1, wherein
the first reinforcement member includes a first end and a second end in the longitudinal direction,
the second reinforcement member includes a third end and a fourth end in the longitudinal direction,
the first end of the first reinforcement member is positioned at the first end of the flexible wiring plate,
the third end of the second reinforcement member is positioned at the second end of the flexible wiring plate,
the second end of the first reinforcement member faces the fourth end of the second reinforcement member.

13. The flexible wiring plate according to claim 1, wherein
a length of the flexible wiring plate in the longitudinal direction substantially corresponds to a length of the edge of the display panel.
